(19) United States
(12) Patent Application Publication
(10) Pub. No.: US 2002/0050569 A1
(43) Pub. Date: May 2, 2002

(54) Magnetic scanning system with a nonzero field

(76) Inventor: Donald W. Berrian, Topsfield, MA (US)

Correspondence Address: Curtis A. Vock, Esq., LATHROP & GAGE L.C., Suite 300, 4845 Pearl East Circle, Boulder, CO, 80301, US

(21) Appl. No.: 10/002,649

(22) Filed: Oct. 19, 2001

Related U.S. Application Data
(60) Provisional application No. 60/242,286, filed on Oct. 20, 2000.

(51) Int. Cl. H01J 37/147

(52) U.S. Cl. 250/396 ML; 250/492.21

(57) ABSTRACT

An apparatus and a method are disclosed for producing a magnetic deflection field in an ion implanter that drives a secondary solenoid field 90 degrees out of phase with the magnetic deflection field. The apparatus has a magnetic structure including two cores and a yoke, the two cores defining a gap therebetween. The magnetic structure being constructed of a ferrimagnetic material to reduce eddy currents. A deflection coil is positioned inside the gap for producing a time-varying magnetic field in the gap and a secondary helical coil is also positioned inside the gap and extends longitudinally for a portion of the gap. The secondary helical coil produces a solenoid magnetic field that is coupled to the magnetic field associated with the deflection coil. A capacitor is associated with the secondary helical coil and tunes the solenoid magnetic field to the fundamental frequency of the magnetic field associated with the deflection coil.

### RELATED APPLICATIONS

This application claims priority to U.S. Provisional Application No. 60/242,286, entitled “Magnetic Scanning System with Non Zero Field”, filed Oct. 20, 2000 and incorporated herein by reference.

### FIELD OF THE INVENTION

This invention relates to magnetic systems, such as ion implanters, that scan heavy ion beams of atoms and molecules of the elements. More particularly, the present invention is directed to a magnetic system and method that uses the magnetic scanning field to drive a solenoid field 90 degrees out of phase with the scanning field parallel to the ion beam.

### BACKGROUND OF THE INVENTION

Many industrial and scientific applications require surfaces to be uniformly irradiated by ion beams such as, for example, the modification of silicon wafers for semiconductors. Because the physical size of the wafer or substrate (e.g., about 5 inches in diameter or more) is larger than the cross-sectional area of the irradiating beam (e.g., about 2 inches in diameter or less), the required uniform irradiance is commonly achieved by scanning the beam across the wafer, scanning the wafer through the beam, or a combination of these techniques.

Ion implanters using magnetic fields to scan the beam across the substrate have an advantage at high beam currents and low energies over electrostatic scanners since electrostatic scanners remove the neutralizing electrons and cause space-charge repulsion to broaden the ion beam producing an unmanageably large beam envelope. For these ion implanters, it is desirable to have a high beam scan rate over the substrate since the irradiance uniformity is more immune to changes in the ion beam flux, a higher wafer throughput is possible at low dose levels and, for high-dose applications, degradation from local surface charging, thermal pulsing, and local particle-induced phenomena such as sputtering and radiation damage are greatly reduced.

A known technique to achieve a high beam scan rate uses a time-varying electric field to scan the beam back and forth in one direction, while the wafer is reciprocated in another direction. A concern with these implanters is that the beam current and hence rate at which wafers can be processed is severely limited by the space-charge forces which act in the region of the time-varying electric deflection fields. In ion implanters, heavy ions, such as those derived from the elements of boron, nitrogen, oxygen, phosphorus, arsenic, or antimony, are generated and formed into a beam by an ion source (see e.g., The Physics and Technology of Ion Sources, Ed. Ian G. Brown, John Wiley & Sons, New York 1989). This ion source produces a high-perveance ion beam that is accelerated by an adjustable voltage power supply. Electrons generated by the energizing of this ion beam become trapped or confined within the ion beam. In the vacuums used in ion implanters a sufficient number of electrons are generated by the beam, within fractions of a millisecond, to maintain the charge-neutrality of the beam. Thus, the ion beam is nearly electrically neutral in the absence of external electric fields and insulating surfaces. Under such conditions, the ion beam is transported in the ion implanter through regions of high vacuum without exhibiting beam divergence from the action of repelling space-charge forces.

However, when this heavy, high perveance ion beam is magnetically scanned, substantial fluctuations occur in the transverse beam size if the scanning magnetic field passes through zero or becomes less than about 50 Gauss. If the above-described effects are not substantially eliminated, or substantially compensated by appropriate correction of the energizing waveform, these fluctuations degrade the uniformity of irradiation on a downstream substrate.

The solutions to this problem have been directed to maintaining the magnetic flux above zero by superimposing a direct current “DC” magnetic field. For instance, U.S. Pat. No. 5,481,116, the disclosure of which is incorporated herein by reference, teaches the use of secondary coils disposed adjacent the gap between the pole faces to produce a secondary magnetic field in the gap. The superimposed primary and secondary fields have a resultant magnitude sufficiently large to prevent the transverse cross-section of the beam from substantially fluctuating in size while the beam is being scanned across the selected surface. If this secondary field is parallel to the primary field, however, the secondary field must be larger than the peak scanning field, which requires significant power. Alternatively, if this secondary field is perpendicular, the field requires a double loop to avoid deflecting the beam, which creates a null between the loops.

Another proposed solution disclosed in U.S. Pat. No. 5,672,879, involves superimposing a DC magnetic field from a separate magnetic structure. This solution is feasible only if the normal magnetic return path in the laminated core is removed. This doubles the effective air gap encountered by the scanning field and doubles the current needed for scanning. The disclosure of the '879 patent is incorporated herein by reference.

The present invention is directed to a more efficient magnetic scanning system with a nonzero magnetic field and method for using this system without the need for a DC supply or extra magnetic structure to generate the bias field.

### SUMMARY OF THE INVENTION

The present invention addresses the conditions that can occur and have been observed in magnetic ion beam scanning, and it provides techniques to enhance the radiation uniformity, accuracy and repeatability of ion beam scanning. The invention addresses the sudden change in the beam emittance (i.e., the area occupied by all of the ions when displayed on a plot of ion angle versus position) when the scanning magnetic field used to scan the ion beam passes through or approaches zero.

According to one aspect of the invention, a magnetic system has been invented for producing a strong magnetic field modulated at a fundamental frequency of at least 20 Hz for uniformly scanning ion beams. A magnetic field in accordance with the invention substantially eliminates or compensates the above-described effect. In another aspect, an apparatus in accordance with the invention includes: a magnetic scanning structure having cores with respective core faces that define therebetween a working gap through which the ion beam passes, the magnetic structure being constructed of a ferrimagnetic material to reduce eddy currents and includes a deflection coil positioned inside the gap for producing a time-varying magnetic field in the gap, a secondary helical coil positioned inside the gap and extending longitudinally for a portion of the gap, the secondary helical coil producing a solenoid magnetic field that is coupled to the magnetic field associated with the deflection coil, and a capacitor associated with the secondary helical coil for tuning the solenoid magnetic field to the fundamental frequency of the magnetic field associated with the deflection coil, the resulting solenoid field being 90 degrees out of phase with the deflector field.

Other features and advantages of the invention will become apparent from the following description and from the claims.

### BRIEF DESCRIPTION OF THE DRAWINGS

FIG. 1 is a perspective view of the core of the magnetic system and the primary and secondary coils constructed according to the invention;

FIG. 2 is a graphic representation of the time-varying magnetic field that may be produced by the magnetic system;

FIG. 3 is a cross-sectional view of the core taken along line 3B3 of FIG. 1 showing the solenoid field produced by the magnetic system of the present invention; and

FIG. 4 is an end view of the core showing the primary deflection field of the magnetic system of the present invention.

### DESCRIPTION OF THE PREFERRED EMBODIMENTS

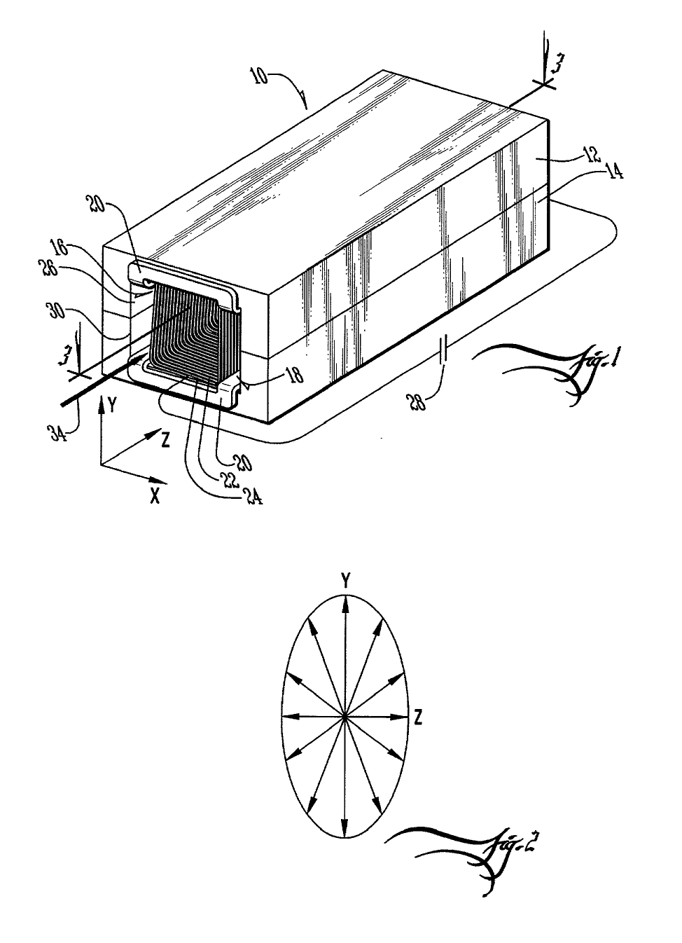

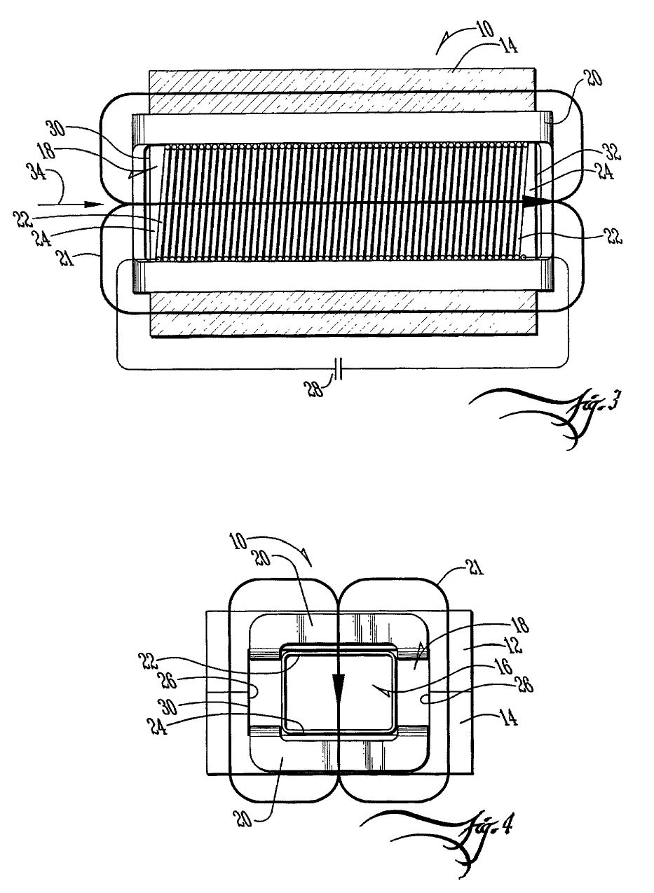

Referring to FIGS. 1 and 3, a magnetic deflector of the present invention for producing time-varying magnetic fields is indicated generally at 10. The deflector 10 includes a pair of cores 12 and 14, each having a channel formed therein, indicated generally at 16, that as the cores are placed together define a rectangular working gap 18. The deflector 10 further includes primary deflection coils 20 and secondary coils 22 extending through at least a portion of the working gap of the deflector.

As shown in FIG. 1, the magnetic deflector is symmetrical about the median plane (i.e., the xz-plane) of working gap 18. The working gap 18 of deflector 10 has an entrance edge 30 and an exit edge 32. The ion beam 34 is transported through working gap 18 from entrance edge 30 to exit edge 32 in a vacuum of typically better than 10⁻⁵ millibar in order to avoid loss and scattering of ions via interaction with gaseous molecules. Preferably, the cores 12 and 14 are made of a high permeability, ferrimagnetic material. The use of ferrimagnetic material is preferred for the deflector because the main deflection field and the solenoid field produced by the primary deflection coils 20 and secondary coils 22, respectively, travel through the deflector. The ferrimagnetic core reduces eddy currents. It would be difficult to construct a laminated structure that produced low eddy currents for both fields.

The primary deflection coils 20 are comprised of a pair of coils, each positioned in the working gap at the face 24 of the channel 16 of a respective core 12 and 14, and adjacent to the opposing side walls 26, as shown in FIGS. 1 and 4. The magnetic scanning field is produced by passing an electric current through the pair of primary deflection coils 20. As shown in FIG. 4, the primary magnetic field flux 21 is established in one direction inside the boundary of the coils and in the opposite direction in the cores 12, 14 outside the boundary of the coil.

The secondary coil 22 is wound as a helix inside working gap 18. Preferably, the secondary coil 22 is located at the peripheral portion of the working gap 18, but inside primary deflection coils 20. The helical secondary coils 22 produce a solenoid field parallel to the ion beam as current is passed therethrough. As shown in FIG. 3, the magnetic field flux of the secondary coil is established parallel to the direction of the ion beam path 34 inside the working gap 18 and in the opposite direction in the cores outside the boundary of the secondary coils 22.

Secondary coil 22 couples to the magnetic scanning field of the primary deflection coil 20. The turn ratio for the coupled primary deflection coil 20 and secondary coil 22 is N:1, where N is the number of turns in the primary coil. The secondary coil makes a single loop around the core and therefore looks like a one-turn secondary to the primary magnetic field.

A capacitor 28 is placed across secondary coils 22 to tune the frequency of the secondary coil 22 to the fundamental frequency of the magnetic scanning field of the primary deflection coil 20. The resulting current in the secondary coil is 90 degrees out of phase with the scan current in the primary coil due to the series resonance of the secondary coil 22 and the capacitor 28. As such, the resulting solenoid field is 90 degrees out of phase with the time varying primary magnetic field such that the solenoid field is at its maximum as the magnetic scanning field associated with the primary coils 20 passes through zero. Although the secondary coil 22 absorbs some power from the primary deflection coil 20, the secondary coil only needs to generate approximately 50 Gauss (versus 2000 Gauss for the primary deflection field) to reduce or eliminate the substantial fluctuations that can occur in the transverse beam size.

The invention thus attains the objects set forth above and those apparent from the preceding description. Since certain changes may be made in the above systems and methods without departing from the scope of the invention, it is intended that all matter contained in the above description or shown in the accompanying drawing be interpreted as illustrative and not in a limiting sense.

In view of the foregoing, what is claimed is:

1. In an ion implanter, an apparatus for producing a magnetic deflection field and a secondary solenoid field, the solenoid field being out of phase with the magnetic deflection field for maintaining the resultant field of the apparatus above zero, the apparatus comprising,
a ferrite magnetic core with a rectangular gap for receiving an ion beam of the ion implanter, the rectangular gap having opposing upper and lower faces and opposing sides,
a deflection coil extending along at least one side of the gap for a portion of the gap, the deflection coil having a magnetic field associated therewith,
a secondary helical coil extending longitudinally for a portion of the gap and having a solenoid magnetic field associated therewith, the secondary coil being coupled to the magnetic field associated with the deflection coil, wherein a current from the secondary coil is substantially 90 degrees out of phase with a scan current in the deflection coil.

2. In an ion implanter, the apparatus of claim 1 further comprising a capacitor across the secondary coil for tuning the coil to resonance.

3. In an ion implanter, the apparatus of claim 1 wherein the apparatus comprises a pair of deflection coils.

4. In an ion implanter, the apparatus of claim 3 wherein the pair of deflection coils are positioned within the gap such that a deflection coil is positioned adjacent to the upper face and a deflection coil is positioned adjacent the lower face.

5. In an ion implanter, the apparatus of claim 1 wherein the gap has a length and the deflection coil extends longitudinally along the entire length of the gap.

6. In an ion implanter, the apparatus of claim 5 wherein the secondary helical coil extends longitudinally along the entire length of the gap.

7. In an ion implanter, the apparatus of claim 1 wherein the secondary coil forms a single loop around the core.

8. An apparatus for producing a magnetic deflection field that drives a secondary solenoid field 90 degrees out of phase with the magnetic deflection field comprising:
a magnetic structure including a ferrimagnetic core to reduce eddy currents, the core defining a gap for receiving the ion beam,
at least one deflection coil extending longitudinally inside the gap for producing a time-varying magnetic field in the gap,
a secondary helical coil positioned inside the gap and extending longitudinally for a portion of the gap, the secondary helical coil producing a solenoid magnetic field that is coupled to the magnetic field associated with the deflection coil, and
a capacitor associated with the secondary helical coil for tuning the solenoid magnetic field to the fundamental frequency of the magnetic field associated with the deflection coil, the solenoid magnetic field being 90 degrees out of phase with the magnetic field associated with the deflection coil.

9. A method for scanning an ion beam over a selected surface comprising the steps of:
providing a scanning magnet comprising
a ferrite magnetic core defining a rectangular gap for receiving the ion beam, the rectangular gap having opposing upper and lower faces and opposing sides,
a deflection coil extending along at least one side of the gap for producing a time-varying magnetic field in the gap,
a secondary helical coil extending longitudinally for a portion of the gap and having a solenoid magnetic field associated therewith, the secondary coil being coupled to the magnetic field associated with the deflection coil, wherein a current from the secondary coil is substantially 90 degrees out of phase with a scan current in the deflection coil,
passing an ion beam into the gap along a first beam path, and
energizing the deflection coil to produce the time-varying magnetic field, the deflection coil driving the secondary coil to produce the solenoid magnetic field 90 degrees out of phase with the scan current such that a resultant magnetic field for the scanning magnet is above zero.

10. A method for scanning an ion beam over a selected surface comprising the steps of:
passing the beam through a rectangular gap of a ferrite magnetic core;
producing a time varying magnetic field in a rectangular gap; and generating a current 90 degrees out of phase with a current associated with the time varying magnetic field.

11. The method for scanning of claim 10 further comprising the step of: generating a field 90 degrees out of phase with the time varying magnetic field.
